(19) United States
(12) Patent Application Publication
(10) Pub. No.: US 2012/0190138 A1
(43) Pub. Date: Jul. 26, 2012

(54) SEMICONDUCTOR MANUFACTURING APPARATUS AND SEMICONDUCTOR SUBSTRATE BONDING METHOD

(75) Inventors: Kazumasa TANIDA, Oita (JP); Satoshi Hongo, Oita (JP); Naoko Yamaguchi, Kanagawa (JP); Kenji Takahashi, Ibaraki (JP); Hideo Numata, Kanagawa (JP)

(73) Assignee: KABUSHIKI KAISHA TOSHIBA, Tokyo (JP)

(21) Appl. No.: 13/354,734

(22) Filed: Jan. 20, 2012

(30) Foreign Application Priority Data
Jan. 21, 2011 (JP) 2011-011314

(51) Int. Cl. H01L 21/66; B32B 37/30; B32B 41/00

(52) U.S. Cl. 438/14; 156/350; 257/E21.53

(57) ABSTRACT

According to one embodiment, semiconductor manufacturing apparatus includes a first member that holds a first semiconductor substrate; a second member that holds a second semiconductor substrate in a state where a bonding surface of the second semiconductor substrate faces a bonding surface of the first semiconductor substrate; a distance detecting unit that detects a distance between the bonding surface of the first semiconductor substrate and the bonding surface of the second semiconductor substrate; an adjusting unit that adjusts the distance between the bonding surface of the first semiconductor substrate and the bonding surface of the second semiconductor substrate to a predetermined value by moving at least one of the first and second members based on a detection result of the distance detecting unit; and a third member that forms the bonding start point between the first semiconductor substrate and the second semiconductor substrate.

### CROSS-REFERENCE TO RELATED APPLICATIONS

This application is based upon and claims the benefit of priority from Japanese Patent Application No. 2011-011314, filed on Jan. 21, 2011; the entire contents of which are incorporated herein by reference.

### FIELD

Embodiments described herein relate generally to a semiconductor manufacturing apparatus and a semiconductor substrate bonding method.

### BACKGROUND

When manufacturing a backside-illuminated image sensor in which a light receiving surface of photodiodes is provided on a back surface of a semiconductor substrate, a method is used in which a support substrate having approximately the same diameter is directly bonded to the front side of the semiconductor substrate on the surface of which photodiodes and integrated circuits are formed and mechanical grinding or chemical mechanical polishing (Chemical Mechanical Polishing: CMP) is performed toward the front surface, on which the photodiodes are formed, from the back surface of the semiconductor substrate to thin the semiconductor substrate.

When bonding the semiconductor substrate and the support substrate, if the support substrate is deformed or the distance between the semiconductor substrate and the support substrate varies greatly, timing of forming a bonding interface deviates or isotropic extension of a bonding interface is impaired, which becomes a factor of forming a void or an unbonded portion. Presence of a void or an unbonded portion between the semiconductor substrate and the support substrate results in yield loss due to separation of the semiconductor substrate from the support substrate and fracture of the semiconductor substrate. Moreover, at the time of bonding, if the support substrate is deformed, the semiconductor substrate is also deformed. In the case of a backside-illuminated image sensor, if the semiconductor substrate is deformed, displacement occurs between color filters and microlenses formed on the back side and photodiodes and integrated circuits formed on the front side, so that the imaging property degrades.

### BRIEF DESCRIPTION OF THE DRAWINGS

FIG. 1 is a cross-sectional view of a semiconductor manufacturing apparatus according to a first embodiment;

FIG. 2 is a partial plan view of the semiconductor manufacturing apparatus according to the first embodiment;

FIG. 3 is a cross-sectional view of the semiconductor manufacturing apparatus when bonding is started;

FIG. 4 is a cross-sectional view of a semiconductor manufacturing apparatus according to a second embodiment;

FIG. 5 is a cross-sectional view of a semiconductor manufacturing apparatus according to a third embodiment; and

FIG. 6 is a cross-sectional view of a semiconductor manufacturing apparatus according to a fourth embodiment.

### DETAILED DESCRIPTION

In general, according to one embodiment, semiconductor manufacturing apparatus forms a bonding start point by bringing bonding surfaces of first and second semiconductor substrates into point contact with each other and bonds the first semiconductor substrate and the second semiconductor substrate over an entire surface by causing the bonding to extend to a periphery from the bonding start point. The semiconductor manufacturing apparatus includes a first member that holds the first semiconductor substrate; a second member that holds the second semiconductor substrate in a state where the bonding surface of the second semiconductor substrate faces the bonding surface of the first semiconductor substrate held by the first member; a distance detecting unit that detects a distance between the bonding surface of the first semiconductor substrate held by the first member and the bonding surface of the second semiconductor substrate held by the second member; an adjusting unit that adjusts the distance between the bonding surface of the first semiconductor substrate and the bonding surface of the second semiconductor substrate to a predetermined value by moving at least one of the first and second members based on a detection result of the distance detecting unit; and a third member that is arranged at a predetermined distance from the second member and forms the bonding start point between the first semiconductor substrate and the second semiconductor substrate by pressurizing one point on a surface opposite to one of the bonding surfaces of the first and second semiconductor substrates.

Exemplary embodiments of semiconductor manufacturing apparatus and semiconductor substrate bonding method will be explained below in detail with reference to the accompanying drawings. The present invention is not limited to the following embodiments.

### First Embodiment

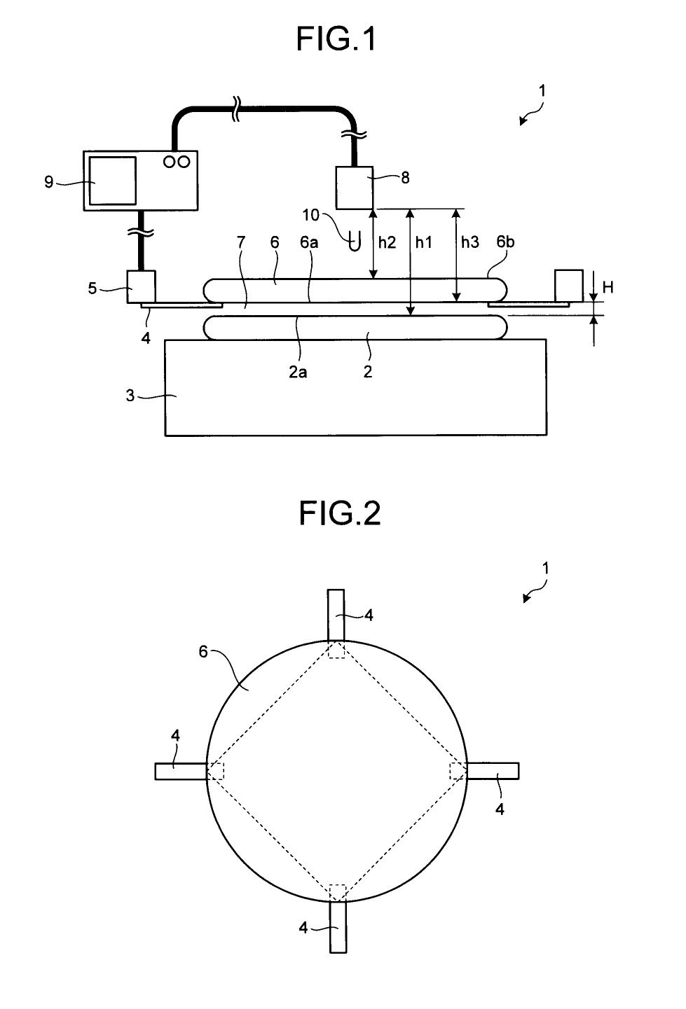

FIG. 1 is a cross-sectional view of a semiconductor manufacturing apparatus according to the first embodiment. FIG. 2 is a partial plan view of the semiconductor manufacturing apparatus according to the first embodiment. In the drawings, the same reference numerals denote the same or similar parts.

A semiconductor manufacturing apparatus 1 is an apparatus that bonds a first substrate 2 as a first semiconductor substrate and a second substrate 6 as a second semiconductor substrate. The semiconductor manufacturing apparatus 1 includes a first member 3, second members 4, a variable mechanism 5, a first sensor 8, a processing unit 9, and a third member 10.

The first substrate 2 is mounted on the first member 3. The first substrate 2 may be a semiconductor substrate of, for example, silicon, and an active layer (not shown), in which photodiodes and transistors are formed, and a wiring layer (not shown) electrically connected to the active layer are formed on the surface of the first substrate 2 to be covered by a dielectric layer to be a bonding surface 2a. The bonding surface 2a is subjected to a hydrophilic treatment, so that hydroxyl groups are attached to the surface thereof.

The second members 4 are arranged to cover the outer periphery of the bonding surface 2a of the first substrate 2. The variable mechanism 5 is connected to the second members 4. Moreover, the second substrate 6 is mounted on the second members 4 so that a bonding surface 6a faces the bonding surface 2a of the first substrate 2. Consequently, a gap 7 is formed between the first substrate 2 and the second substrate 6. The second substrate 6 is a member for functioning as a reinforcement of the first substrate 2 and is, for example, formed of silicon. The bonding surface 6a is subjected to a hydrophilic treatment, so that hydroxyl groups are attached to the surface thereof.

The second member 4 is provided at two or more locations and keeps the gap 7 constant. The second member 4 can be arranged at a plurality of arbitrary locations to place and hold the second substrate 6, however, deformation of the second substrate 6 at the time of bonding can be made symmetric by holding the second substrate 6 at vertices of a regular polygon (an equilateral triangle or a square as shown in FIG. 2) centered on the center of gravity of the second substrate 6.

The second member 4 may have any shape as long as the gap 7 can be formed between the first substrate 2 and the second substrate 6. As an example, the second member 4 may be formed into a shape such as a plate shape, a sloped shape, a columnar shape, and a conical shape. The second member 4 preferably has a conical shape for reducing the contact area with the bonding surfaces 2a and 6a of the substrates as much as possible.

Moreover, any material can be selected as the material of the second members 4, and, for example, metal such as aluminum, ceramic, a resin material (for example, SAS resin (Silicone rubber-Acrylonitrile-Styrene copolymer resin)), or the like can be used. In order to prevent metal contamination of a substrate (the first substrate 2 and the second substrate 6) as a bonding target, a material other than metal is desirably used as the material of the second members 4, and, for example, metal contamination can be prevented by using a resin material such as fluorine resin and polyetheretherketone.

The gap 7 is measured by the first sensor 8 as a distance H between the bonding surface 2a of the first substrate 2 and the bonding surface 6a of the second substrate 6. Specifically, for example, after the first substrate 2 is mounted on the first member 3, a distance h1 from the bonding surface 2a of the first substrate 2 is measured by the first sensor 8. Next, after the second substrate 6 is held by the second members 4, a distance h2 from a back surface 6b of the second substrate 6 is measured by the first sensor 8. Next, the distance H of the gap 7 is calculated by the processing unit 9 by the calculation of H=h1−h2−t, in which t is a thickness of the second substrate 6. The value t is preset in the processing unit 9 as a predetermined value. In this manner, in the present embodiment, a distance detecting unit is realized by the first sensor 8 and the processing unit 9.

Moreover, the processing unit 9 is electrically connected to the variable mechanism 5, so that the gap 7 can be adjusted to a desired distance by operating the variable mechanism 5. In other words, in the present embodiment, an adjusting unit can be realized by the processing unit 9 and the variable mechanism 5.

The first member 3 may include a stage-like adsorption mechanism, and an adsorption method may be any method such as a vacuum chuck (a plurality of holes, grooves, a porous body, or a combination thereof) and an electrostatic chuck. In the case of a vacuum chuck, the stage material may be a ceramic material such as glass, quartz, silicon, an inorganic material, and aluminum oxide (Al₂O₃), a resin material such as PTFE (polytetrafluoroethylene), polyetheretherketone, and conductive polyetheretherketone mixed with carbon, stainless steel particles, or the like, however, heavy-metal contamination, such as Cu, of the back surface of the first substrate 2 can be eliminated by forming the first member 3 from an inorganic material or a resin material. In the case of an electrostatic chuck, aluminum nitride (AlN), aluminum oxide, single crystal sapphire, or the like can be used.

The first member 3 includes a flat stage-like adsorption mechanism, so that even when the first substrate 2 is distorted, bonding can be performed after correcting the first substrate 2 to be flat. When the first substrate 2 is a substrate on which wires are formed in addition to photodiodes and transistors, the first substrate 2 is warped easier as the first substrate 2 becomes thinner due to the surface stress of metal forming the wires. Therefore, bonding failure does not occur easily by correcting the warpage of the first substrate 2 by causing the first substrate 2 to be adsorbed onto the first member 3. On the other hand, although the second substrate 6, which functions as a reinforcement, is provided with a protection film or the like on its surface in some cases, the second substrate 6 is basically just a semiconductor wafer (for example, bare silicon wafer), so that warpage thereof is generally small. Therefore, the effect of preventing occurrence of the bonding failure becomes high by causing the first substrate 2, on which photodiodes, transistors, wires, and the like are formed, to be adsorbed onto the flat stage-like first member 3 compared with a case of causing the second substrate 6 that functions as a reinforcement to be adsorbed onto the first member 3.

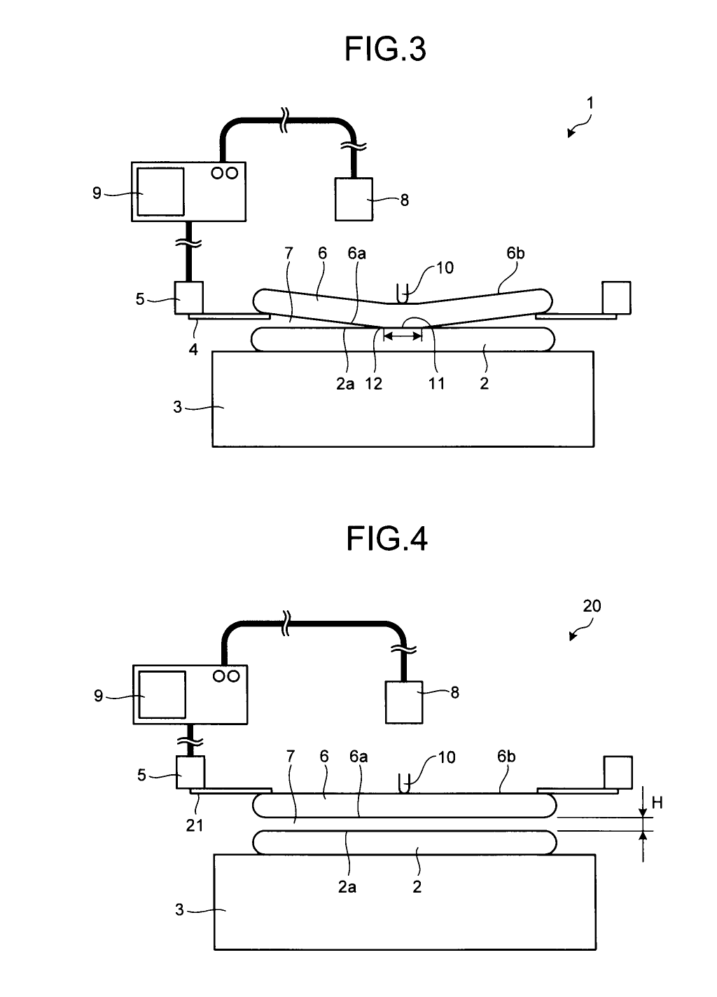

FIG. 3 is a cross-sectional view of the semiconductor manufacturing apparatus when bonding is started. As shown in FIG. 3, the bonding surface 2a of the first substrate 2 and the bonding surface 6a of the second substrate 6 are brought into point contact with each other by pressurizing the back surface 6b side of the second substrate 6 by the third member 10 arranged at a predetermined distance from the second members 4, so that hydroxyl groups attached to the bonding surface 2a and hydroxyl groups attached to the bonding surface 6a are hydrogen bonded to each other, thereby forming a bonding start point 11. Hydrogen bonding extends to the periphery from the bonding start point 11, so that a bonding interface 12 extends isotropically and the first substrate 2 and the second substrate 6 are bonded over the entire surface. The tip end shape of the third member 10 may be a flat surface or a needle shape, however, because it is desirable to apply pressure locally for forming the bonding start point 11 with high reproducibility and, moreover, in terms of a wear resistance, a hemispherical shape having a predetermined curvature is preferable. If the second members 4 are retracted from between the first substrate 2 and the second substrate 6 at a timing at which the bonding start point 11 is formed, the second members 4 do not hinder extension of the bonding interface 12. When the first member 3 includes an absorption mechanism, extension of the bonding interface 12 is not hindered by stopping absorption at the same timing.

Moreover, in FIG. 3, the bonding start point 11 is formed at the center of the first substrate 2 and the second substrate 6. The bonding start point 11 may be formed at any point as long as the bonding start point 11 can be away from the second members 4 by a predetermined distance, however, when a plurality of the second members 4 is arranged, the bonding start point 11 is preferably coaxial with the center of gravity (center) of the second substrate 6 for causing the second substrate 6 to deform symmetrically and causing the bonding interface to extend isotropically at the time of bonding.

The first substrate 2 and the second substrate 6 are cleaned before being conveyed into the semiconductor manufacturing apparatus 1 to remove organic substances such as carbon and metal contaminations such as Cu and Al on the surfaces of the bonding surfaces 2a and 6a. In other words, because variation in the surface state of the bonding surfaces 2a and 6a is reduced, calculation of the extension rate of the bonding interface 12 becomes easy. Therefore, it is possible to estimate the time until the bonding interface 12 reaches the second members 4 after the bonding start point 11 is formed, so that the processing unit 9 causes the second members 4 to retract in the circumferential direction by driving the variable mechanism 5 before the bonding interface 12 reaches the second members 4, thereby preventing a void from being generated by entraining an air layer and preventing extension of the bonding interface from being stopped halfway and an unbonded portion from being formed.

The cleaning process may be a wet process such as an organic cleaning using acetone, alcohol, ozone water (O₃), or the like, and an acid and alkaline cleaning using hydrofluoric acid (HF), diluted hydrofluoric acid (DHF), sulfuric acid hydrogen peroxide mixture, ammonia hydrogen peroxide mixture, hydrochloric acid hydrogen peroxide mixture, or the like. Alternatively, the cleaning process may be a dry process such as a plasma process energized by a single gas, such as hydrogen, nitrogen, oxygen, nitrous oxide (N₂O), argon, and helium or a plurality of gases. The cleaning process may be a combination of the wet process and the dry process. Although both the bonding surface 2a of the first substrate 2 and the bonding surface 6a of the second substrate 6 are preferably processed by the cleaning process, only any one of the surfaces may be processed.

As the first sensor 8, a sensor using any of a single wavelength laser, visible light, infrared light, X-ray, ultrasonic wave, and the like can be applied as long as the distance between the bonding surface 2a of the first substrate 2 and the back surface 6b of the second substrate 6 can be measured. Moreover, when the second substrate 6 does not allow visible light to pass therethrough, such as silicon, the distance h1 to the bonding surface 2a of the first substrate 2 is desirably measured before arranging the second substrate 6 as in the above embodiment, however, the distance h2 from the back surface 6b of the second substrate 6 may be measured concurrently after arranging the second substrate 6 by using light having a wavelength capable of passing through the second substrate 6 such as infrared light.

Moreover, a distance h3 between the bonding surface 6a of the second substrate 6 and the first sensor 8 may be directly measured. In this case, the distance H of the gap 7 is calculated by H=h1−h3 and it is not needed to preset the thickness of the second substrate 6 to a predetermined value or measure it in advance.

Moreover, the first sensor 8 may be a contact sensor. Furthermore, in the present embodiment, the positions of the second members 4 are changed by using the variable mechanism 5, however, the configuration may be such that the gap 7 can be adjusted to a desired distance by making the position of the first member 3 variable. Moreover, the positions of both the first member 3 and the second members 4 may be made adjustable.

According to the semiconductor manufacturing apparatus 1 in the present embodiment, the first member 3 holds the first substrate 2 and the second members 4 hold the second substrate 6 to cause the bonding surface 2a of the first substrate 2 and the bonding surface 6a of the second substrate 6 to face each other, and the distance between the back surface 6b of the second substrate 6 pressurized by the third member 10 and the bonding surface 2a of the first substrate 2 is measured by the first sensor 8. Then, the distance H between the bonding surface 2a of the first substrate 2 and the bonding surface 6a of the second substrate 6 is calculated and the distance between the bonding surface 2a of the first substrate 2 and the bonding surface 6a of the second substrate 6 is adjusted to be small by moving at least one of the first member 3 and the second members 4. Consequently, deformation of the second substrate 6 when being pressurized by the third member 10 can be reduced.

Moreover, because the repulsive force of the second substrate 6 pressurized and deformed by the third member 10 becomes small, the bonding surface 2a of the first substrate 2 and the bonding surface 6a of the second substrate 6 can be easily brought close to each other by pressurization, so that deviation of the formation timing of the bonding interface 12 can be made small. Therefore, the second members 4 do not hinder extension of the bonding interface 12, so that an excellent bonding state can be obtained without forming an entrained void in the bonding interface 12 between the first substrate 2 and the second substrate 6. Moreover, distortion of the first and second substrates 2 and 6 after bonding can be reduced.

Furthermore, the second members 4 are arranged between the first substrate 2 and the second substrate 6 and cover at least two locations of the outer periphery of the first substrate 2, and the second substrate 6 is mounted on the surfaces of the second members 4 opposite to the surfaces facing the first substrate 2, so that the distance between the bonding surface 2a of the first substrate 2 and the bonding surface 6a of the second substrate 6 can be easily adjusted.

Explanation of a backside-illuminated image sensor is supplemented.

In a backside-illuminated image sensor, wires and excessive films need not be formed on a light receiving surface, so that sensitivity higher than a frontside-illuminated image sensor can be obtained. At this time, in order to efficiently collect light incident on a back surface into photodiodes, a semiconductor substrate needs to be thinned. The thickness of a semiconductor substrate, for example, needs to be thinner than 20 μm in the case of receiving visible light for preventing the resolution from being impaired before being collected in photodiodes due to diffusion of charges generated in a light receiving surface.

A semiconductor device including such a backside-illuminated image sensor is formed by the following method. First, a semiconductor substrate on the surface of which photodiodes and integrated circuits are formed is prepared. A support substrate having approximately the same diameter is bonded to the front surface side of the semiconductor substrate. This support substrate functions as a reinforcement when thinning the semiconductor substrate to near the photodiodes from the back surface side thereof and forming a light receiving surface. Next, an antireflection film, color filters, condenser microlenses, and the like are provided on the light receiving surface, whereby a so-called backside-illuminated image sensor is formed that receives an energy line such as light and electrons emitted from the back surface side and collects it in the photodiodes. Furthermore, after forming electrode portions, which are electrically connected to the integrated circuits, on the back surface of the semiconductor substrate, a bonded body of the semiconductor substrate and the support substrate is cut and divided into chips by a dicing blade. The divided chip is adhered to a ceramic package or the like, and the electrode portion of a chip and wires formed in the ceramic package are electrically connected by wire bonding, whereby a semiconductor device is formed.

In the above semiconductor device, the semiconductor substrate is thinned partway by mechanical grinding or chemical mechanical polishing from the back surface of the semiconductor substrate toward a layer on the front surface in which photodiodes are formed, and the semiconductor substrate is desirably made as thin as possible for collecting an energy line into the photodiodes efficiently.

However, thinning of the semiconductor substrate results in concentration of a residual stress, which is generated when integrated circuits (formed of a metal wire and a dielectric film) are formed on the surface of the semiconductor substrate, on the bonding surface side of the semiconductor substrate and the support substrate. Moreover, a high-temperature process is needed for forming electrodes on the back surface of the semiconductor substrate, so that the bonding method of the semiconductor substrate and the support substrate is desirably a direct bonding method in which the surface portion of the semiconductor substrate and the surface portion of the support substrate are directly connected inorganically without via an organic material.

In the direct bonding method according to the present embodiment, a bonding source point (bonding start point) is formed by applying pressure to a predetermined one point of both bonding surfaces on which a hydrophilic treatment is performed, and a bonding interface by hydrogen bonding extends spontaneously and isotropically from that point. However, if a semiconductor substrate or a support substrate is deformed at the time of pressurization or the distance between the semiconductor substrate and the support substrate varies greatly, timing of forming the bonding interface deviates, isotropic extension of the bonding interface is impaired and an air layer is entrained to generate a void, or extension of the bonding interface stops halfway to form an unbonded portion. Unless a void or an unbonded portion formed in the bonding interface is made as small as possible, when thinning the semiconductor substrate, yield decreases due to separation of the semiconductor substrate from the support substrate, fracture of a thin semiconductor substrate, or the like. Moreover, even if separation or fracture doe not occur, an integrated circuit formed on the semiconductor substrate is distorted due to the effect of deformation of the support substrate at the time of bonding, so that misalignment occurs when forming color filters and microlenses on the back surface of the semiconductor substrate and therefore the imaging property degrades.

However, in a conventional semiconductor manufacturing apparatus, if the distance between substrates to be bonded is made small, the substrates may be unintentionally in contact with each other and bonding may start, so that the distance between the substrates is difficult to be made small.

According to the semiconductor manufacturing apparatus in the present embodiment, because the distance between substrates to be bonded can be detected, the distance between the substrates can be made as small as possible. Therefore, it is possible to suppress deformation of the support substrate and variation in the distance between the substrates at the time of bonding of the semiconductor substrate and the support substrate, so that yield is improved. Moreover, when the semiconductor manufacturing apparatus is used for manufacturing a backside-illuminated image sensor, degradation of the imaging property can be prevented.

### Second Embodiment

FIG. 4 is a cross-sectional view of a semiconductor manufacturing apparatus according to the second embodiment. Components same as those in the first embodiment are given the same reference numerals and explanation thereof is omitted. In FIG. 4, the first substrate 2 is mounted on the first member 3 of a semiconductor manufacturing apparatus 20. The first substrate 2 may be, for example, a semiconductor substrate, and an active layer (not shown), in which photodiodes and transistors are formed, and a wiring layer (not shown) electrically connected to the active layer are formed on the surface of the first substrate 2 to be covered by a dielectric layer to be the bonding surface 2a.

The second substrate 6 is arranged so that the bonding surface 6a faces the bonding surface 2a of the first substrate 2. The outer periphery of the back surface 6b of the second substrate 6 is adsorbed by second members 21. Moreover, the variable mechanism 5 is connected to the second members 21.

In the similar manner to the first embodiment, the second members 21 desirably hold the second substrate 6 at vertices of a regular polygon (an equilateral triangle, a square, or the like) centered on the center of gravity of the second substrate 6 so that deformation of the second substrate 6 at the time of bonding can be made symmetric, however, the second members 21 may hold the second substrate 6 at a plurality of arbitrary locations or by being formed into a ring shape. An adsorption method may be any method such as a vacuum chuck (a plurality of holes, grooves, a porous body, or a combination thereof) and an electrostatic chuck. In the case of a vacuum chuck, the stage material may be a ceramic material such as glass, quartz, silicon, an inorganic material, and aluminum oxide, a resin material such as PTFE, polyetheretherketone, and conductive polyetheretherketone mixed with carbon, stainless steel particles, or the like, however, heavy-metal contamination, such as Cu, of the back surface of the second substrate 6 can be eliminated by forming the second members 21 from an inorganic material or a resin material. In the case of an electrostatic chuck, aluminum nitride, aluminum oxide, single crystal sapphire, or the like can be used.

The second member 21 may include a stage-like adsorption mechanism. If the second member 21 includes a flat stage-like adsorption mechanism and adsorbs the entire surface of the back surface 6b of the second substrate 6, the second substrate 6 can be bonded to the first substrate 2 while preventing deformation of the second substrate 6 such as sagging of the central portion. In this case, if a vacuum chuck is employed, the second member 21 is formed of a transparent material such as quartz and acrylic, and a sensor using light such as infrared light is applied as the first sensor 8, the gap 7 can be calculated in the similar manner to the first embodiment. Moreover, if an opening for measuring the distance by the first sensor 8 is provided in the second member 21, even if the second member 21 is formed of a material, such as silicon, through which visible light does not pass, the first sensor 8 using visible light can be applied. Moreover, the third member 10 can pressurize the surface opposite to the bonding surface 6a of the second substrate 6 by providing an opening in a position corresponding to the third member 10. When the first member 3 includes an absorption mechanism, extension of the bonding interface is not hindered by stopping absorption at the timing at which the bonding start point is formed.

When the first member 3 does not include an absorption mechanism, the effect of preventing occurrence of the bonding failure becomes high by causing the first substrate 2, on which photodiodes, transistors, wires, and the like are formed, to be adsorbed onto the second members 21 compared with a case of causing the second substrate 6 that functions as a reinforcement to be adsorbed onto the second members 21.

In this embodiment, the gap 7 is adjusted to a desired distance by changing the positions of the second members 21 by using the variable mechanism 5, however, the gap 7 may be adjusted to a desired distance by providing a variable mechanism in the first member 3. Moreover, the positions of both the first member 3 and the second members 21 may be made adjustable.

According to the semiconductor manufacturing apparatus 20 in the present embodiment, in addition to the effects similar to the first embodiment, the distance H between the bonding surface 2a of the first substrate 2 and the bonding surface 6a of the second substrate 6 can be adjusted to be small without being limited by the thickness of the second members 21 by the second members 21 adsorbing the back surface 6b of the second substrate 6. In other words, in the present embodiment, the gap 7 can be made equal to or smaller than the thickness of the second members 21.

### Third Embodiment

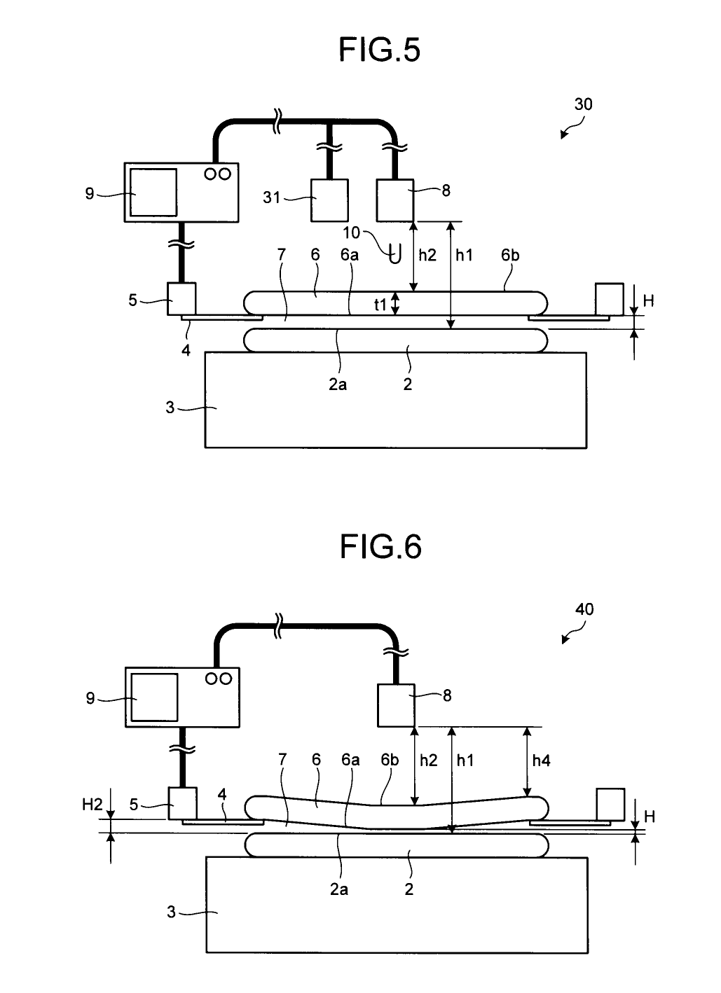

FIG. 5 is a cross-sectional view of a semiconductor manufacturing apparatus according to the third embodiment. Components same as those in the first embodiment are given the same reference numerals and explanation thereof is omitted. In FIG. 5, a semiconductor manufacturing apparatus 30 includes a second sensor 31. The second sensor 31 is a sensor capable of measuring a thickness t1 of the second substrate 6. Moreover, the semiconductor manufacturing apparatus 30 can measure the distance between the back surface 6b of the second substrate 6 and the bonding surface 2a of the first substrate 2 by the first sensor 8.

The gap 7 is measured by the first sensor 8 and the second sensor 31 as the distance H between the bonding surface 2a of the first substrate 2 and the bonding surface 6a of the second substrate 6. Specifically, for example, after the first substrate 2 is adsorbed onto the first member 3, the distance h1 from the bonding surface 2a of the first substrate 2 is measured by the first sensor 8. Next, after the second substrate 6 is held by the second members 4, the distance h2 from the back surface 6b of the second substrate 6 is measured by the first sensor 8. Next, the thickness t1 of the second substrate 6 is measured by the second sensor 31. Next, the distance H of the gap 7 is calculated by the processing unit 9 by the calculation of H−h1−h2−t1. In other words, in the present embodiment, a distance detecting unit is configured by the first sensor 8, the second sensor 31, and the processing unit 9.

As the second sensor 31, for example, a sensor using any of a single wavelength laser, visible light, infrared light, X-ray, ultrasonic wave, and the like can be applied, however, when the second substrate 6 is formed of silicon, a sensor using infrared light is desirable. As the second sensor 31, for example, a sensor that measures the thickness by an interference fringe method can be applied. In this embodiment, the case of configuring the first sensor 8 and the second sensor 31 separately is explained as an example, however, they may be configured as the same sensor unit.

According to the semiconductor manufacturing apparatus 30 in the present embodiment, in addition to the effects similar to the first embodiment, the distance H of the gap 7 between the bonding surface 2a of the first substrate 2 and the bonding surface 6a of the second substrate 6 can be calculated accurately and adjusted to be small by measuring the thickness t1 of the second substrate 6 by the second sensor 31. Therefore, deformation of the second substrate 6 when pressurizing the second substrate 6 by the third member 10 can be reduced. Furthermore, deviation of the formation timing of the bonding interface by pressurization can be made further small. Therefore, the second members 4 do not hinder extension of the bonding interface, so that an excellent bonding state can be obtained without forming an entrained void in the bonding interface between the first substrate 2 and the second substrate 6 and distortion after bonding can be reduced.

### Fourth Embodiment

FIG. 6 is a cross-sectional view of a semiconductor manufacturing apparatus according to the fourth embodiment. In FIG. 6, components same as those in other embodiments are given the same reference numerals and explanation thereof is omitted. In FIG. 6, a semiconductor manufacturing apparatus 40 includes the first sensor 8 and heights h2 and h4 are measured at least at two locations, i.e., in the outer periphery and near the center of the back surface 6b of the second substrate 6 by using the first sensor 8 to measure the shape of the second substrate 6.

If h2≠h4, that is, if the second substrate 6 is deformed, as shown in FIG. 6, the distance H of the gap 7 between the central portion of the bonding surface 2a of the first substrate 2 and the central portion of the bonding surface 6a of the second substrate 6 and a height H2 (distance between the outer peripheral portion of the bonding surface 2a of the first substrate 2 and the outer peripheral portion of the bonding surface 6a of the second substrate 6) held by the second members 4 do not always become equal. When the second substrate 6 is deflected downward, if the height H2 of the second members 4 is lowered by the distance H or more, the bonding surface 2a of the first substrate 2 and the bonding surface 6a of the second substrate 6 come into contact with each other. Therefore, the height H2, at which the second substrate 6 is held by the second members 4, is control to be H+(h2−h4), so that contact between the bonding surfaces can be avoided. In this embodiment, the distance H is a value calculated by h1−h2−t, and specifically, for example, after the first substrate 2 is mounted on the first member 3, the distance h1 from the bonding surface 2a of the first substrate 2 is measured by the first sensor 8. Next, after the second substrate 6 is held by the second members 4, the distance h2 from near the portion of the second substrate 6 pressurized by the third member 10, that is, the back surface 6b near the center of gravity of the second substrate 6 is measured by the first sensor 8, and next, the distance h4 from the outer periphery (near the portion held by the second members 4) of the second substrate 6 is measured by the first sensor 8. Next, the distance H of the gap 7 is calculated by the processing unit 9 by H=h1−h2−t. The value t is preset in the processing unit 9 as a predetermined value. Furthermore, the processing unit 9 determines whether the second substrate 6 is deformed based on the values of h2 and h4, and, when the second substrate 6 is deformed, controls the height H2, at which the second substrate 6 is held by the second members 4, to H+(h2−h4). The processing unit 9 is electrically connected to the variable mechanism 5, so that the gap 7 can be adjusted to a desired distance by operating the variable mechanism 5.

In this embodiment, the gap 7 is adjusted to a desired distance by moving the second members 4 by the variable mechanism 5, however, the gap 7 may be adjusted to a desired distance by providing the variable mechanism 5 in the first member 3 and moving the first member 3.

According to the semiconductor manufacturing apparatus 40 in the present embodiment, in addition to the effects similar to the first embodiment, deformation of the second substrate 6 held by the second members 4 is calculated by measuring the distance from the second substrate 6 at least at two locations, i.e., in the outer periphery and near the center of the back surface 6b of the second substrate 6 by the first sensor 8, so that the gap 7 can be adjusted without causing the bonding surface 2a of the first substrate 2 and the bonding surface 6a of the second substrate 6 to come into contact with each other.

When the variable mechanism 5 can move each second member 4 independently, the first sensor 8 may be capable of measuring the distance h4 at a plurality of locations in the outer periphery of the second substrate 6. The distance H of the gap 7 is calculated by measuring the distance h4 near each second member 4 and each second member 4 is independently moved according to the calculation result of the gap 7, so that even if the second substrate 6 is deformed, bonding to the first substrate 2 can be started in a state where the second substrate 6 is corrected to be flat and held. Consequently, the bonding interface can be extended isotropically from the bonding start point.

In each of the above embodiments, the third member 10 pressurizes the surface opposite to the bonding surface 6a of the second substrate 6, however, the third member 10 can be configured to pressurize the surface opposite to the bonding surface 2a of the first substrate 2. Moreover, in each of the above embodiments, the first substrate 2 is a substrate including photodiodes, transistors, wires, and the like and the second substrate 6 is a substrate that functions as a reinforcement of the first substrate 2, however, they may be interchanged.

Moreover, the above embodiments can be combined and performed. For example, it is possible that the back surface of the second substrate is adsorbed and held by the second member and the second sensor measures the thickness of the second substrate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor manufacturing apparatus that forms a bonding start point by bringing bonding surfaces of first and second semiconductor substrates into point contact with each other and bonds the first semiconductor substrate and the second semiconductor substrate over an entire surface by causing the bonding to extend to a periphery from the bonding start point, the apparatus comprising:
a first member that holds the first semiconductor substrate;
a second member that holds the second semiconductor substrate in a state where the bonding surface of the second semiconductor substrate faces the bonding surface of the first semiconductor substrate held by the first member;
a distance detecting unit that detects a distance between the bonding surface of the first semiconductor substrate held by the first member and the bonding surface of the second semiconductor substrate held by the second member;
an adjusting unit that adjusts the distance between the bonding surface of the first semiconductor substrate and the bonding surface of the second semiconductor substrate to a predetermined value by moving at least one of the first and second members based on a detection result of the distance detecting unit; and
a third member that is arranged at a predetermined distance from the second member and forms the bonding start point between the first semiconductor substrate and the second semiconductor substrate by pressurizing one point on a surface opposite to one of the bonding surfaces of the first and second semiconductor substrates.

2. The semiconductor manufacturing apparatus according to claim 1, wherein
the distance detecting unit includes a first sensor that measures a distance between the bonding surface of the first semiconductor substrate held by the first member and a surface opposite to the bonding surface of the second semiconductor substrate held by the second member, and calculates the distance between the bonding surface of the first semiconductor substrate held by the first member and the bonding surface of the second semiconductor substrate held by the second member based on a measurement result of the first sensor and a value registered in advance as a thickness of the second semiconductor substrate.

3. The semiconductor manufacturing apparatus according to claim 2, wherein the second member is arranged between the first semiconductor substrate and the second semiconductor substrate, covers an outer peripheral portion of the first substrate at a plurality of locations, and places and holds the second semiconductor substrate on a side opposite to a surface facing the first semiconductor substrate.

4. The semiconductor manufacturing apparatus according to claim 3, wherein the second member has a conical shape.

5. The semiconductor manufacturing apparatus according to claim 3, wherein
a plurality of the second members is provided, and
the second members hold the second substrate at a vertex of a regular polygon centered on a center of gravity of the second substrate.

6. The semiconductor manufacturing apparatus according to claim 5, wherein the third member forms the bonding start point at a center of the second substrate.

7. The semiconductor manufacturing apparatus according to claim 2, wherein the second member holds the second semiconductor substrate by adsorbing the surface opposite to the bonding surface of the second semiconductor substrate.

8. The semiconductor manufacturing apparatus according to claim 2, wherein the first member includes a stage-like adsorption mechanism that corrects a warpage of the first substrate by adsorbing the first substrate.

9. The semiconductor manufacturing apparatus according to any one of claims 3, wherein
the first sensor measures the distance between the surface opposite to the bonding surface of the second semiconductor substrate and the bonding surface of the first semiconductor substrate in a central portion and a outer peripheral portion of the second semiconductor substrate, and
the adjusting unit moves the second member so that the distance between the bonding surface of the second semiconductor substrate and the bonding surface of the first semiconductor substrate becomes a predetermined value in the central portion of the second semiconductor substrate.

10. The semiconductor manufacturing apparatus according to claim 1, wherein
the distance detecting unit includes a first sensor that measures a distance between the bonding surface of the first semiconductor substrate held by the first member and a surface opposite to the bonding surface of the second semiconductor substrate held by the second member and a second sensor that measures a thickness of the second semiconductor substrate, and calculates the distance between the bonding surface of the first semiconductor substrate held by the first member and the bonding surface of the second semiconductor substrate held by the second member by subtracting a measurement result of the second sensor from a measurement result of the first sensor.

11. The semiconductor manufacturing apparatus according to claim 10, wherein the second member is arranged between the first semiconductor substrate and the second semiconductor substrate, covers an outer peripheral portion of the first substrate at a plurality of locations, and places and holds the second semiconductor substrate on a side opposite to a surface facing the first semiconductor substrate.

12. The semiconductor manufacturing apparatus according to claim 11, wherein the second member has a conical shape.

13. The semiconductor manufacturing apparatus according to claim 11, wherein
a plurality of the second members is provided, and
the second members hold the second substrate at a vertex of a regular polygon centered on a center of gravity of the second substrate.

14. The semiconductor manufacturing apparatus according to claim 13, wherein the third member forms the bonding start point at a center of the second substrate.

15. The semiconductor manufacturing apparatus according to claim 10, wherein the second member holds the second semiconductor substrate by adsorbing the surface opposite to the bonding surface of the second semiconductor substrate.

16. The semiconductor manufacturing apparatus according to claim 10, wherein the first member includes a stage-like adsorption mechanism that corrects a warpage of the first substrate by adsorbing the first substrate.

17. The semiconductor manufacturing apparatus according to any one of claims 11, wherein
the first sensor measures the distance between the surface opposite to the bonding surface of the second semiconductor substrate and the bonding surface of the first semiconductor substrate in a central portion and a outer peripheral portion of the second semiconductor substrate, and
the adjusting unit moves the second member so that the distance between the bonding surface of the second semiconductor substrate and the bonding surface of the first semiconductor substrate becomes a predetermined value in the central portion of the second semiconductor substrate.

18. A semiconductor substrate bonding method of forming a bonding start point by bringing bonding surfaces of first and second semiconductor substrates into point contact with each other and bonding the first semiconductor substrate and the second semiconductor substrate over an entire surface by causing the bonding to extend to a periphery from the bonding start point, the method comprising:
holding the first semiconductor substrate by a first member;
holding the second semiconductor substrate by a second member in a state where the bonding surface of the second semiconductor substrate faces the bonding surface of the first semiconductor substrate held by the first member;
detecting a distance between the bonding surface of the first semiconductor substrate held by the first member and the bonding surface of the second semiconductor substrate held by the second member;
adjusting the distance between the bonding surface of the first semiconductor substrate and the bonding surface of the second semiconductor substrate to a predetermined value by moving at least one of the first and second members based on detected distance between the bonding surface of the first semiconductor substrate and the bonding surface of the second semiconductor substrate; and
forming the bonding start point between the first semiconductor substrate and the second semiconductor substrate by pressurizing one point on a surface opposite to one of the bonding surfaces of the first and second semiconductor substrates by a third member arranged at a predetermined distance from the second member.

19. The semiconductor substrate bonding method according to claim 18, wherein
the distance between the bonding surface of the first semiconductor substrate held by the first member and the bonding surface of the second semiconductor substrate held by the second member is detected by
measuring a distance between the bonding surface of the first semiconductor substrate held by the first member and a surface opposite to the bonding surface of the second semiconductor substrate held by the second member, and
calculating the distance between the bonding surface of the first semiconductor substrate held by the first member and the bonding surface of the second semiconductor substrate held by the second member based on the distance between the bonding surface of the first semiconductor substrate and the surface opposite to the bonding surface of the second semiconductor substrate and a value registered in advance as a thickness of the second semiconductor substrate.

20. The semiconductor substrate bonding method according to claim 18, wherein
the distance between the bonding surface of the first semiconductor substrate held by the first member and the bonding surface of the second semiconductor substrate held by the second member is detected by
measuring a distance between the bonding surface of the first semiconductor substrate held by the first member and a surface opposite to the bonding surface of the second semiconductor substrate held by the second member,
measuring a thickness of the second substrate, and
calculating the distance between the bonding surface of the first semiconductor substrate held by the first member and the bonding surface of the second semiconductor substrate held by the second member by subtracting the thickness of the second substrate from the distance between the bonding surface of the first semiconductor substrate and the surface opposite to the bonding surface of the second semiconductor substrate.
